(19) United States
(12) Patent Application Publication
(10) Pub. No.: US 2011/0297203 A1
(43) Pub. Date: Dec. 8, 2011

(54) FORMATION OF THERMOELECTRIC ELEMENTS BY NET SHAPE SINTERING

(75) Inventors: James R. Salvador, Lansing, MI (US); Jihui Yang, Lakeshore (CA); Andrew A. Wereszczak, Oak Ridge, TN (US)

(73) Assignee: GM GLOBAL TECHNOLOGY OPERATIONS, INC., Detroit, MI (US)

(21) Appl. No.: 12/793,798

(22) Filed: Jun. 4, 2010

(51) Int. Cl. H01L 35/14; B29C 43/00

(52) U.S. Cl. 136/239; 264/104

(57) ABSTRACT

Practices are described for preparing fine-grain, stress-tolerant, brittle, doped semiconductor thermoelectric elements better suited to withstand thermal and mechanical loads without cracking or fracture. Preparation entails net shape powder processing of substantially isotropic thermoelectric compounds such as skutterudites under conditions which promote reduction of the largest grain sizes in a grain size distribution. Nearly three-fold improvements in fracture strength over conventionally-processed thermoelectric elements are observed. The net shape powder processing is adapted for the ready incorporation of the net shape thermoelectric elements into a thermoelectric device.

This invention was made with U.S. Government support under Agreement No. DEACO50000R22725 awarded by the Department of Energy. The U.S. Government may have certain rights in this invention.

### TECHNICAL FIELD

This disclosure pertains to the making of thermoelectric elements (sometimes called thermoelectric “legs”) and their assembly into a thermoelectric device. Materials having thermoelectric properties are often brittle and susceptible to cracking. This disclosure pertains to the use of sintering techniques to produce fine-grained thermoelectric legs to their net design shape and to the assembly of the legs into a thermoelectric device without changing the net shape of the legs or otherwise increasing the susceptibility of the legs to fracture or cracking.

### BACKGROUND OF THE INVENTION

Thermoelectric devices are formed of two different (but complementary) thermoelectric materials and can produce an electrical current when separated junctions are subjected to a suitable temperature differential or can produce separate hot and cold junctions when powered with an electrical current. The power generation thermoelectric devices exploit the Seebeck effect, a phenomenon in which a temperature gradient is applied across a body and as a result an open circuit voltage, co-linear to the temperature gradient, is established. The sign of the voltage with respect to the applied temperature gradient is dependent on the nature of the majority charge carriers. Where a temperature difference exists between ends of a thermoelectric element, heated electrons (or holes) flow towards the cooler end. Where a pair of dissimilar thermoelectric semiconductor elements, that is a pair consisting of an n-type and a p-type element, are suitably connected together to form an electrical circuit, a direct current (DC) flows in that circuit.

Several families of crystalline thermoelectric material compounds have been discovered and developed. Among these compounds, skutterudite (CoSb₃) is an example. Cubic CoSb₃ possesses two voids in a crystallographic unit cell. The voids may be filled to some extent, for example, with rare-earth, alkaline-earth, or alkali metal elements. Such partial filling approaches may be used to adjust or tune thermoelectric properties of the crystalline material. The skutterudites display semiconductor properties and distinct compositions can be formed with p-type and n-type conductivity. Many other thermoelectric compositions are known and available.

To date, however, all practical such thermoelectric materials are brittle, narrow band gap semiconductors. In automotive applications, thermoelectric devices comprising thermoelectric legs of these ceramic materials are subjected to very harsh operating environments. The devices are often situated where they are subjected to substantial mechanical forces, including vibrational forces. And the thermoelectric legs, which are often only a few millimeters in length, are subjected to substantial temperature differences over that short length which induces stresses in the legs. Such stresses affect the viability of the brittle materials and, therefore, acceptance of their use in automotive vehicle applications.

Thermoelectric compositions are generally prepared by mixing powders of elemental or pre-combined constituents in a convenient mass or volume and fusing or sintering them into an billet of a suitable composition. Once suitable crystalline compositions have been formulated it is necessary to form p-type and n-type thermoelectric legs of a desired size and shape for incorporation into a thermoelectric device, comprising many legs arranged for electrical interconnections for producing an electrical potential or a heating or cooling effect. In order to more effectively produce thermoelectric materials and to shape them into thermoelectric legs for a device, machining of ingots of the brittle materials has been employed at some stage of manufacture. It is a purpose of this disclosure and invention to provide a method of preparing thermoelectric elements (legs) in which the legs of thermoelectric material are formed to a net shape without machining and thereafter assembled into a thermoelectric device without machining the net shape formed legs.

### SUMMARY OF THE INVENTION

The inventors of the methods disclosed in this specification have carefully considered reasons for the relatively low strength and durability of thermoelectric legs as they have been made and assembled into thermoelectric devices. They have observed that thermoelectric legs made by prior practices have strength-limiting flaws in the ceramic material that lead to breakage when subjected to mechanical forces, such as vibration, or to thermal shock. Strength limiting flaws can be intrinsic in nature taking the form of large grains, agglomerates or cracks which are on the interior of the brittle, crystalline specimen and initiate failure internally. Other flaws include surface flaws in which failure of the leg initiates from flaws associated with surface imperfections. These surface flaws can be intrinsic flaws inherent in parallelepiped leg shapes or extrinsic flaws resulting from machining or other processes employed in fabricating legs of suitable shape. The inventors' goal is to use a method of making thermoelectric legs or other elements in which the size of the strength limiting flaws introduced into the legs are limited to the dimensions of the largest grains in the sample (up to ten to fifteen microns) of the thermoelectric material so as to obtain increased strength in the elements of a thermoelectric device. This increased strength is to enable application of the devices, for example, on automotive vehicles.

In accordance with preferred embodiments of the methods of this invention, thermoelectric material compositions are obtained as powders in a desired grain size by any suitable practice. For example, the average grain size of n-type and p-type skutterudite compositions may be of the order of about ten microns, and it is preferred that the quantity of grains significantly larger than the average grain size be minimized. A suitable weight or volume of a powder of a composition may then be carefully loaded into a forming cavity, defining the shape of the leg, for axial compaction and sintering into the net shape of a desired thermoelectric leg. One or many such legs are then formed in separate cavities by net shape sintering into durably compacted legs. The sintered legs are used in the assembly, or otherwise making, of a designed thermoelectric device without any machining or processing of the legs which would introduce additional flaws into their surfaces or internal structure. In a preferred practice, spark plasma sintering (SPS) is used to fuse the powder into the dense leg shapes. SPS passes very large currents through the compacted powder and the resulting Joule heating quickly consolidates the leg(s). It could be used to simultaneously produce many legs in side-by-side forming cavities. But hot pressing and subsequent sintering practices may also be used to achieve consolidated net shapes.

By the term “net shape” it is intended that the sintered elements be fabricated with such dimensional control that no additional shaping is required, so that no extrinsic flaw is introduced in the elements and no remediation of any damage from such shaping is necessary. Thus, each of the thermoelectric elements of a device, n-type and p-type, are prepared by net shape sintering and thereafter assembled into a thermoelectric device without machining or exposure to other processes which may inflict damage or deform the surfaces of any of the legs of the device.

In addition to the net shape, sinter forming of fine grain powder thermoelectric legs, consideration may also be given to their cross-sectional shape. Often, the legs of a thermoelectric device are square in cross-section and cut to a desired length for placement of many closely spaced, like-shaped p-type and n-type legs between electrodes to be bonded in electrical contact with the ends of the legs. In addition to avoiding machining of the thermoelectric material legs, it may be preferred to sinter them into round or rounded cross-sections without sharp edges.

### BRIEF DESCRIPTION OF THE DRAWINGS

FIG. 1 shows an operating representative thermoelectric module for producing electric power, comprising an assemblage of many p-type and n-type semiconductor elements electrically connected in series. The assemblage and its associated electrical conductors are positioned between two planar ceramic isolators, with one isolator exposed to a higher temperature than the other.

FIG. 2A shows an array of semiconductor thermoelectric elements arranged in a similar manner to that shown in FIG. 1 used to model the thermal stresses under representative operating conditions. Overlaid on FIG. 2A is plane ABCD which identifies the six thermoelectric elements represented and shown in FIG. 2B. FIG. 2B shows at least the maximum tensile stress contours corresponding to the six elements of plane ABCD.

FIG. 3 shows a fragmentary view of a body containing an internal and an external strength-limiting flaw under influence of a tensile stress.

FIG. 4A shows a perspective view of a cylindrical form suitable for use in practice of the invention comprising, in plan view, a closed curve with regions of concave curvature. FIG. 4B illustrates that the form of FIG. 4A enables close packing of elements.

FIGS. 5A and 5B show views of individual punches and dies suitable for compacting powder to a cylindrical faun. In FIG. 5A the punch acts in a direction parallel to the cylinder axis; in FIG. 5B the punch acts in a direction perpendicular to the cylinder axis.

### DESCRIPTION OF ILLUSTRATIVE EMBODIMENTS

Thermoelectric devices generate electricity by electrically connecting two thermoelectric elements of differing thermopower signs and exposing them to a temperature gradient. The capabilities of the device will depend both on the magnitude of the Seebeck coefficient of the thermoelectric elements, a material effect, and the magnitude of the temperature gradient. It is therefore desirable to have the absolute values of Seebeck coefficients be as large as possible.

Semiconductors are attractive candidate materials for thermoelectric elements because they may be doped with elements providing excess electrons or holes which results in large positive or negative values of the Seebeck coefficient of these materials depending on the charge of the excess carriers.

While doped semiconductors have suitable thermoelectric properties, they are generally brittle and prone to stochastic fracture under stress. Thermoelectric devices have utility only when exposed to a temperature gradient and temperature gradients are known to induce stresses in bodies. Thus, thermoelectric devices will, in the course of performing their intended function, experience stress. Further, the magnitude of the stress will increase with increasing temperature gradient. Thus, the stresses imposed on the thermoelectric elements will increase in proportion to the electrical output of the device. Conversely, any stress limitation imposed on the device will also limit its allowable electrical output. Accordingly, it is desired to make and assemble the thermoelectric elements so that they do not break or fracture in the handling or operation of a thermoelectric device.

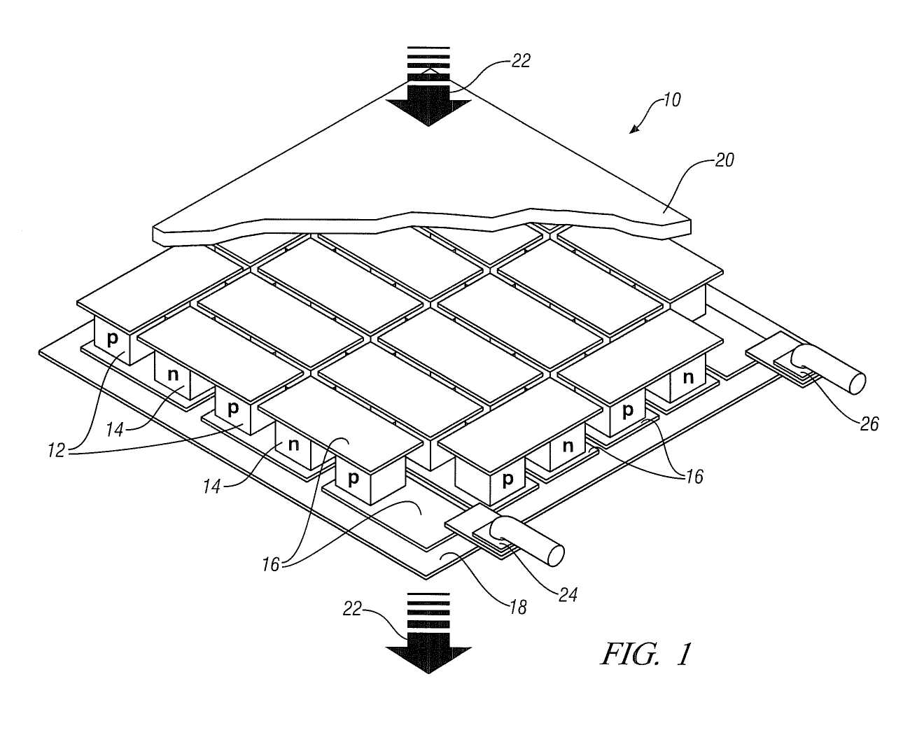

FIG. 1 shows a representative thermoelectric device 10, comprising a regular array of spaced-apart, alternating p-type 12 and n-type 14 thermoelectric elements connected to one another in series configuration by interconnected conductors 16 and attached to a plate at their top and bottom surfaces. Often both types of elements 12, 14 are the same size and shape. For example, they are square in cross-section for close-fitting and a few millimeters on a side. Their heights are uniform and of a few millimeters. In this illustration, seventeen p-type elements and seventeen n-type elements are alternately and progressively connected as p-type/n-type pairs in series DC connection from terminal 24 to terminal 26. In operation, the produced current flows from one terminal, up and down, through adjacent elements 12, 14 and conductors 16 to the other terminal.

In this representation it is intended that plate 20, the hot plate, is maintained at a higher temperature than plate 18, the cold plate. Obviously such a temperature gradient will produce a heat flow in the direction indicated by arrow 22. Electrical terminals 24 and 26 provide connection with an external load or with another thermoelectric device. In the configuration shown connector 26 will be at a more positive electrical potential that connector 24.

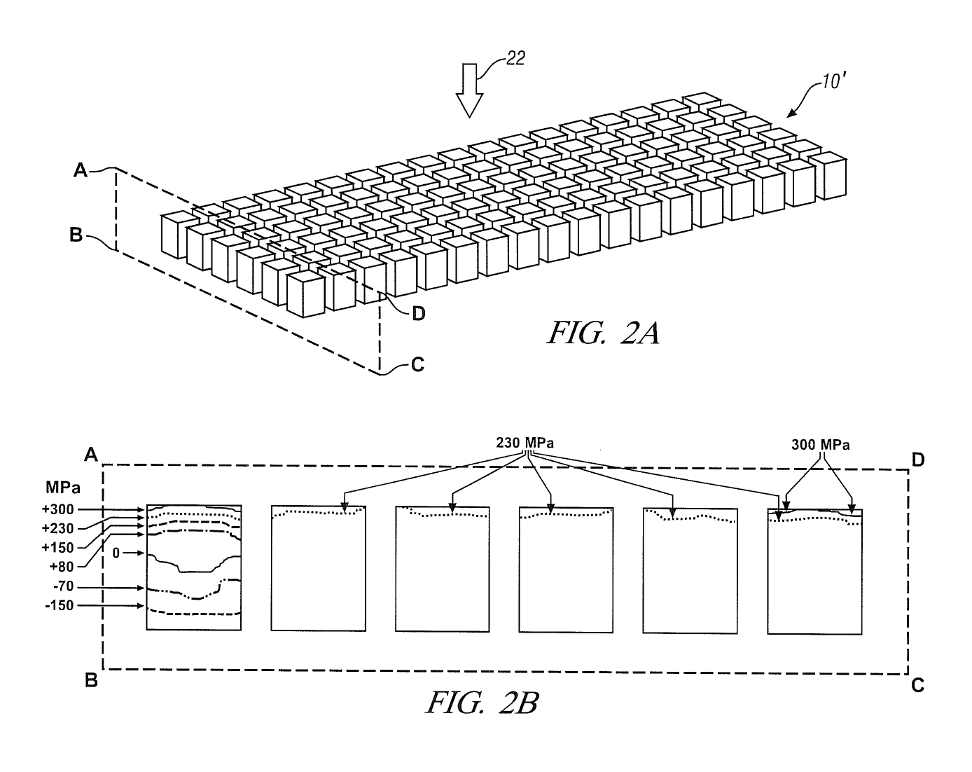

FIG. 2A shows a thermoelectric device comprising an array of thermoelectric elements 10′, comparable to that shown in FIG. 1. The magnitude of stresses induced in the elements of this array during operation under representative conditions was modeled using a coupled thermal and mechanical finite element analysis model employed by the program ANSYS. (Other commercial finite element analysis software could have been used.) The results for the six elements lying in the plane ABCD are shown in FIG. 2B. The results are representative of a temperature on the hot side of the device equal to 525° C. with the cold side maintained at about 80° C. leading to heat flow in the direction indicated by arrow 22. The results are shown as stress contours overlaid on the outline of the elements. A generally complete set of stress contours is shown for only one element, that lying closest to line AB. For the remaining elements only the contour line(s) indicating the maximum tensile stresses are shown since these will be most capable of inducing element fracture. It may be noted that tensile stresses in excess of 230×10⁶ Pa are routinely observed on the ends of the elements attached to the hot plate and that selected elements can experience local tensile stresses of over 300 MPa. Of particular significance is that these large stresses occur at the edges and corners of the elements.

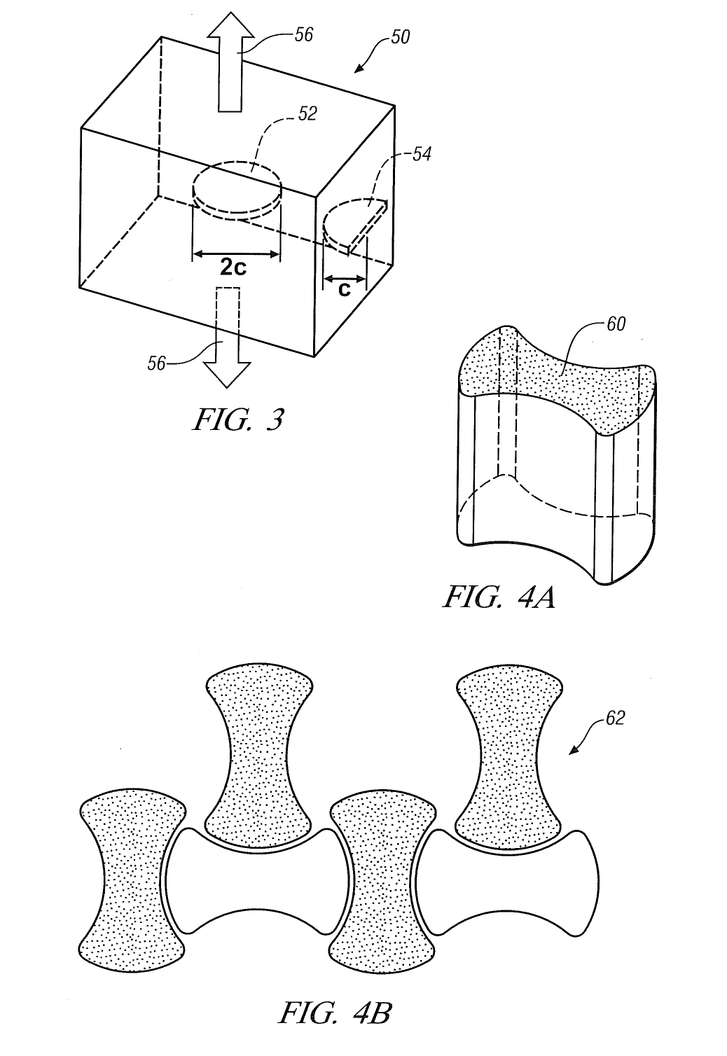

Brittle materials fracture when overloaded or over stressed in tension. The fracture stress of commercial brittle materials, however, is not an intrinsic property of the material itself, but depends on the size of the test sample, the multiaxial stress gradient, and on the number and severity of pre-existing flaws in the material. Strength limiting flaws may include, without limitation, large grains, agglomerates, pores, voids, surface scratches or cracks. FIG. 3 shows a fragmentary view of a body 50 containing an internal strength-limiting flaw 52 of length 2c and an external flaw 54 of length c while under a tensile stress directed as indicated by arrows 56. The plane of strength limiting flaws 52 and 54 is perpendicular to the applied stress direction 56. The fracture stress, σ_{f}, for body 50, corresponding to the stress to cause the flaw to initiate in the body is given by:

σ_{f}=K_{Ic}/(Y·c^{1/2}),

where K_{Ic} is the fracture toughness of the material,

and Y is a unitless geometric factor associated with flaw shape.

Thus σ_{f}∝1/\sqrt{c} and the fracture stress will depend upon the length of the largest suitably-oriented flaw.

Even in this simple configuration, it is clear that two nominally equivalent elements may, depending on their flaw density and distribution, have substantially different failure stresses or fracture strengths. Because of the series electrical connection employed in the device, any fracture has potential to at least severely degrade its performance. Thus, it is desired to fabricate thermoelectric elements which have consistent distributions of small flaws so that all elements will have substantially equivalent fracture strengths. It is of course intended that the element fracture stress be sufficiently greater than even extreme in-service stresses to assure device durability.

It is particularly advantageous to eliminate or reduce surface or external strength-limiting flaws. As FIG. 3 makes clear, a surface crack or flaw of a given length can have the same consequence as an internal flaw of twice its length. In one current approach to manufacturing thermoelectric devices, thermoelectric elements are first fabricated from ingots of Bi₂Te₃ containing elongated oriented crystals. These ingots are first sawed into slabs and are then sawed into regular parallelepipeds. These sawing operations introduce microcracks, scratches, chips, or other extrinsic strength-limiting flaws, which tend to be particularly severe at the corners and edges of the parallelepiped where the damaged layer introduced by the first sawing operation is subjected to the stresses of the second sawing operation. These cracks or flaws are then removed, or at least diminished in length and severity by polishing the sawn surfaces prior to use.

It is a goal of this invention to eliminate the necessity for any mechanical sawing or machining operation by fabricating thermoelectric elements to net shape using powder processing techniques. The term ‘net shape’ is intended to convey that the thermoelectric elements, as fabricated, fully satisfy all dimensional requirements and that no further shaping or dimensional adjustment, no matter how minimal is required or performed.

The process of fabricating the Bi₂Te₃ thermoelectric elements requires that the material possess large oriented grains. In general, the largest crack or other flaw dimensions are comparable to the grain size. Hence, the use of large-grained material may result in large internal flaws which may promote lower failure stresses and be detrimental to mechanical reliability.

It is a goal of this invention to minimize the dimensions of internal strength-limiting flaws by promoting a fine grain size or minimizing the size of the largest grains in an entire grain size distribution.

Finally, because conventional elements are sawed from ingots they will typically exhibit a rectangular cross-section resulting from sawing in two orthogonal directions. The corners or angular junctions formed by the two intersecting sawn surfaces are, unfortunately, very effective stress raisers, that is the local geometry is such that it induces a local stress which is greater than the applied stress. Since these angular junctions also tend to be a frequent origin of damaging cracks, fractures are readily initiated at these angular junctions.

It is a goal of this invention to minimize stress-raising shapes and, in particular, to avoid any angular junctions between surfaces.

Thermoelectric elements fabricated by consolidation and sintering of powders are fabricated as net shape entities and no further processing or manufacturing operations such as sawing is used. Further, the geometry of the powder processed elements is dictated by the geometry of the die and thus may be fabricated in forms with smoothly-varying curvature to ensure that no stress-raising angular features are present. A natural configuration for the sintered elements is a cylinder, but packing considerations, driven by a requirement to maximize the electrical output per unit area may lead to the adoption of other forms, for example an elliptic cylinder or a form 60 like that shown in FIG. 4A which, as shown in plan view in FIG. 4B may be tiled efficiently to form a grouping 62 of thermoelectric legs for a thermoelectric device. In other words, the elliptic cylinder or form 60 is formed of rounded surfaces in cross-section with no sharp edges and the side surfaces of these forms are rounded into their top and bottom surfaces.

The thermopower or Seebeck coefficient of a thermoelectric material is frequently presented as a single value. However the Seebeck ‘coefficient’ is in fact a second rank tensor. Thus, in individual crystals the values of the ‘coefficient’ may vary appreciably with crystal orientation, especially for crystals of low symmetry, many of which, like Bi₂Te₃ find application as thermoelectric elements. Since powder processed thermoelectric elements will comprise a multiplicity of randomly oriented crystals (grains), the net Seebeck ‘coefficient’ will be some average of the Seebeck coefficients of all grains. In highly anisotropic crystals, which may exhibit radically different thermopowers in different crystal orientations, this may unacceptably reduce the overall thermopower of the compact. It is therefore preferred that materials exhibiting higher symmetry, and therefore greater isotropy be employed. Suitable candidate materials are filled skutterudites which have high thermopower and exhibit crystal structures with cubic symmetry rendering their thermoelectric response substantially isotropic.

Exemplary n-type skutterudites are those based on Co and Sb; exemplary p-type skutterudites are those based on Co, Fe and Sb. Both n-type and p-type skutterudites will exhibit enhanced thermoelectric properties when filled with Na, K, Ca, Sr, Ba, La, Ce, Pr, Nd, Eu, Yb and Tl or combinations thereof.

It will be appreciated by consideration of FIG. 1 that in typical application of these thermoelectric elements, equal numbers of p-type and n-type elements will be mounted between substantially-parallel plates. The plate separation will dictate the length of the elements as well as the acceptable tolerance in the length. This, in turn, will influence the quantity, size and distribution of the powders used, the compaction pressure employed, the sintering procedure followed and the desired degree of densification to be achieved.

The procedure entails charging a pre-measured quantity of p-type or n-type semiconductor thermoelectric powder as fine particles of suitable size, on the order of 10 micrometers and a size distribution in the range of 5 to 20 micrometers, fabricated by ball milling, into a pre-shaped chamber; compacting the powders under pressure in the range of 30 to 60 MPa; and consolidating or densifying the powder compact by sintering. Samples are sintered under dynamic vacuum or an inert atmosphere by heating, at a rapid rate between 50 and 100° C./minute with the application of a constant uniaxial pressure to a final temperature where consolidation is complete. Samples are generally allowed to age at this final temperature for 1 to 3 minutes before cooling to room temperature by convection with the pressure removed.

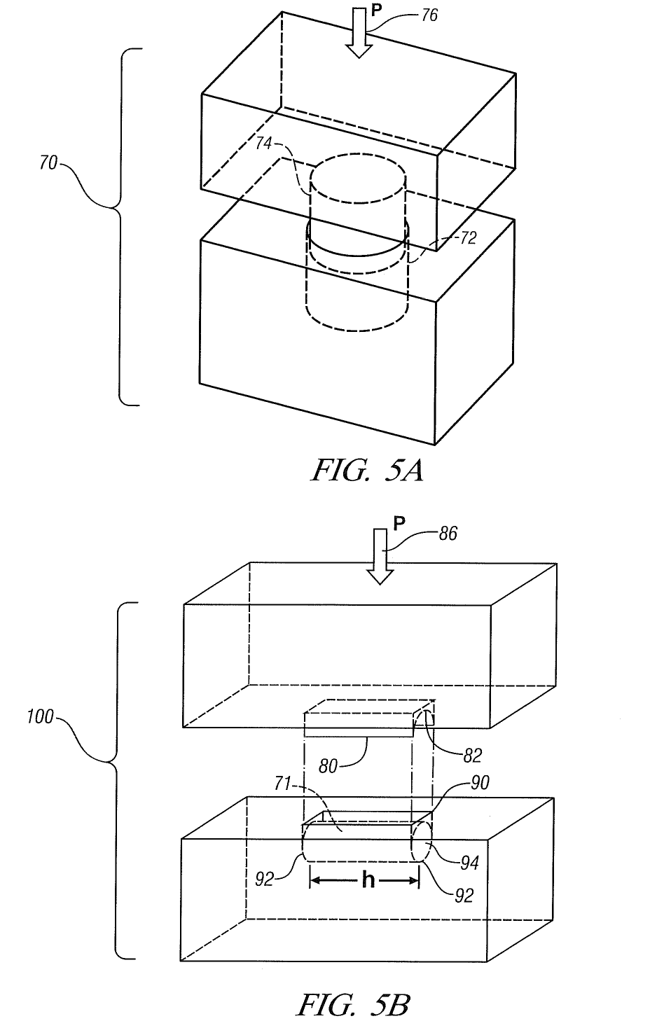

The compacting pressure may be applied in any suitable direction. If the primary concern is ease of die design and freedom from parting lines, visible features on the part along the line of contact of die segments which may result from die wear or from minor mismatch between die halves, compaction along the cylinder axis may be preferred. This configuration is shown in FIG. 5A. An individual die 70 comprising a die cavity 72 with a bottom surface will be charged with powder (not shown) and compacted by application of pressure P applied to punch 74 in a direction corresponding to arrow 76. The diameter of punch 74 is selected to fit tightly within the diameter of die cavity 72. This approach however may render the height or longitudinal dimension, h, of the resulting cylinder very dependent on process consistency since variations in the powder charge or compacting pressure will modify the cylinder height. However such variation may be minimized by utilizing a die with a plurality of substantially-identical die cavities to enable simultaneous fabrication of a plurality of elements of common longitudinal dimension, h. In particular if all the thermoelectric elements of a thermoelectric device can be fabricated as a single batch and only elements from an individual batch are used in a single device, element to element dimensional variance may be minimized.

Compacting in a direction perpendicular to the cylinder axis is shown at FIG. 5B, again showing only a single die 100. Here punch 80 fits closely within die cavity 90 of die 100. The end faces 92, 94 of die cavity 90 define the height, h of compacted cylinder 70 (shown in ghost). The curved surface of compacted cylinder 71 is formed by contact of a quantity of powder charged to the die cavity with curved surface 82 of the punch 80 and curved surface 92 of die cavity 90 when compacted under pressure P applied in the direction of arrow 86. It will be appreciated that under- or over-charging the die cavity 90 with powder, or variation in compacting pressure P may promote flash formation or visible parting lines, or cylinders with an elliptical or racetrack cross-section. However the longitudinal dimension h of cylinder 70 is uniquely established by the mold dimensions, specifically the distance between opposing internal mold faces 92 and 94 and will therefore be consistent even if variations in powder charge or compacting pressure occur.

Again dimensional consistency of the sintered powder compact may be promoted by utilizing a die with a plurality of substantially-identical die cavities to enable simultaneous fabrication of a plurality of elements. It will be appreciated that the use of a die with multiple cavities also enables production efficiencies.

Sintering is commonly used in the consolidation of powder compacts. Sintering seeks to consolidate powders by solid-state diffusion under heat, often with pressure-assistance, and sometimes promoted by addition of minor proportions of a liquid accelerant. In principle, the grain size of the resulting compacted and sintered solid would be substantially equal to the particle size of the powder charge. However, conventional powder processing approaches such as hot pressing, though not excluded, may result in grain growth in the powder charge during consolidation, possibly thereby prejudicing the fracture behavior of the resulting sintered and compacted solid. A preferred process is Spark Plasma Sintering Processing, a sintering process which promotes short process times and minimizes grain growth and coarsening.

Spark Plasma Sintering Processing applies a series of high frequency DC pulses through the compacted powder while it is under pressure. It is believed, but not relied on, that this generates a high current, low voltage spark and momentarily generates a plasma generally localized at points of particle-particle contact. This produces high localized temperatures between particles promoting solid state diffusion at surfaces and consolidation. The sintering process need only be continued for periods of up to 30 minutes, more typically for about 10 minutes, to achieve near complete densification of the compact. Because heating is localized, the bulk temperature of the compact is reduced and only minimal grain growth is generally observed. Hot pressing or other sintering approaches generally result in higher bulk temperatures in the compact during sintering and are thus more likely to promote grain growth. However any sintering process may be used provided that it promotes an average grain size in the sintered compact of less than several micrometers. The process is further illustrated by consideration of the following example.

### Example

P-type skutterudite powder was fabricated by first melting Ce, Co, Fe, and Sb metal in atomic proportions Ce:Co:Fe:Sb of 1.05:1:3:12.05 by induction melting them under an argon atmosphere to form an ingot of CeCoFe₃Sb₁₂. The CeCoFe₃Sb₁₂ was then comminuted by ball milling in acetone under a protective atmosphere of argon for 5 minutes to achieve particle sizes in the a range of 5 to 40 micrometers and annealed for 168 hours at 750° C. under a reduced atmosphere of 10⁻⁶ Torr.

The skutterudite powder was then placed, in a plurality of like shaped and dimensioned cavities contained within a three-part cylindrical graphite die. The die consisted of a smooth-surfaced backing plate; a solid cylindrical die body with recesses on each of its flat, end surfaces, and at about its mid-length a plurality of die cavities open on either end to the flat surfaces of the cylinder; and a combination punch comprising a plurality of individual punches, one for each of the die cavities, extending from a common die plate. The die plate was generally disc-like with one flat surface and with integral punches extending from the opposing surface. The die included alignment features including matched cylindrical cavities in the die body and die plate to releasably secure closely fitting pins, and recesses in the cylinder ends of the die body to tightly accommodate the perimeters of the complementarily-formed combination punch and the backing plate.

The die was assembled by first inserting the backing plate, generally resembling a flat-faced disc into a centered recess in one of the flat faces of a cylindrically-shaped die. The depth of the recess was less than the thickness of the backing plate so that one of the flat surfaces of the backing plate would protrude beyond the end of the cylinder while the second would terminate one end of the open die cavities. After placing the fine-grain skutterudite powder in the die cavities, now closed on one end by the backing plate, the combination punch was installed.

The combination punch was fitted into a centered recess on the second of the flat faces of the cylindrical die. Insertion was guided by the guide pins commonly engaged with the combination punch and die body to align the combination punch and die body and ensure that the individual punches were inserted into their respective die cavities. The flat surface of the combination punch extended beyond the cylindrical body of the die. Thus, compaction pressure, applied to the protruding faces of the backing plate and the combination punch, for example in a press, was transmitted to the skutterudites. The compaction pressure used in fabricating these skutterudite elements was 50 MPa.

The powder compact was then sintered by spark plasma sintering while under an axial load of 50 MPa using a pulsed DC current at a pulse frequency of 70 Hertz and a pulse duration of 12 milliseconds with a 2 millisecond pause. The powders were heated at a rate of 75° C./minute to a final temperature of 675° C. and held for an additional 2 minutes. The total heating time was 10 minutes while under an applied pressure of 50 MPa to form many net-shape processed, square-section shaped 2.5 millimeters×2.5 millimeters×11 millimeters bars at 98% densification. The average grain size was determined to be 7.6 micrometers with a maximum grain size of less than 40 micrometers.

These net-shape processed bars were tested in three-point bending over an 8 mm span. For comparison, equivalently-sized, samples of the same CeCoFe₃Sb₁₂ composition and grain size distribution were sawn from larger sized similarly Spark Plasma Sintering-processed blanks. The blank-sawn samples will therefore exhibit a distribution of strength-limiting extrinsic flaws resulting from the sawing process. These extrinsic flaws are analogous to those of conventionally-processed ingot sawn thermoelectric devices, but with a smaller average flaw size due to the smaller average grain size of the sintered blanks. No such extrinsic flaws are expected for the net-shape processed samples.

The fracture strength of the blank-sawn samples, at a 95% confidence level ranged from 32 to 45 MPa; the net-shape processed samples exhibited fracture strengths between 92 and 112 MPa. The powder processed samples also exhibited appreciably greater consistency in their mechanical strength properties than the ingot sawn samples. Thus the net-shape processed samples exhibited both superior strength and less sample-to-sample variation than the ingot sawn samples.

It will be appreciated that it was intended to directly compare these net-shape processed sintered bars with sawn bars representative of current fabrication procedures. Thus, the sintered bar cross-section was chosen to replicate the square cross-section of the sawn bars although it is recognized that the sharp corners necessarily consequent upon a square cross-section render it sub-optimal for the practice of the invention. Even greater demonstrated benefits of the powder-fabricated thermoelectric elements of the invention over sawn ingot thermoelectric elements are realized when shapes are fabricated without sharp corners.

Although the practices of this invention have been described with reference to specific examples, it will be appreciated that these are intended to be exemplary only and are not intended as limitations on the scope of the invention.

1. A method for fabricating a plurality of stress-tolerant, fine-grain, semiconducting, thermoelectric elements to net shape, the thermoelectric elements exhibiting consistently high fracture strengths, the net shape elements being suitable for assembly as is into a thermoelectric device without further shaping or processing prejudicial to its fracture strength; the method comprising:
charging pre-measured quantities of semiconductor thermoelectric materials into a plurality of die cavities, the semiconductor material being in the form of powder particles, the powder particles having a mean size and a size distribution, and the die cavities being bounded by die surfaces, at least one of which die surfaces may be moved independently;
applying pressure to the semiconductor powder by suitably positioning the moveable die surfaces and thereby forming a plurality of powder compacts in the shape of the die cavities, each of the die cavities being bounded by three surfaces; a first, substantially planar surface bounded by a smooth closed curve; a second surface created by projection of the closed curve by a distance in a direction perpendicular to the plane of the first surface; and a third surface created by the projection of the first surface by the distance in the direction perpendicular to the plane of the first surface, the surfaces being arranged such that the first surface abuts the second surface and the third surface abuts the second surface; and
heating the plurality of powder compacts to form an at least partially densified solid of predetermined dimension.

2. The method of claim 1 wherein the semiconductor thermoelectric material exhibits a cubic crystal structure.

3. The method of claim 1 wherein the semiconductor thermoelectric material is a skutterudite compound comprising Sb and Co for n-type materials and Sb, Co, and Fe for p-type materials.

4. The skutterudite compound of claim 3 further comprising one or more of the elements of the group consisting of Na, K, Ca, Sr, Ba, La, Ce, Pr, Nd, Eu, Yb, In, and Tl.

5. The method of claim 1 wherein the semiconductor thermoelectric material powder has a mean particle size of 5 micrometers and an average flaw size on the order of, or smaller than the largest grain.

6. The method of claim 1 wherein thermoelectric elements exhibit a fracture stress of greater than 100 MPa.

7. The method of claim 1 wherein the smooth closed curve comprises at least a region of concave curvature.

8. The method of claim 1 wherein the thermoelectric element comprises an assemblage of grains with an average grain size of less than 20 micrometers.

9. The method of claim 1 wherein the measured quantities of powder are compacted and sintered by spark plasma sintering.

10. A sintered, net shape, fine-grained, polycrystalline semiconducting thermoelectric element having an average grain size and a fracture stress; and comprising three surfaces; a first, substantially planar surface bounded by a smooth closed curve; a second surface created by projection of the closed curve by a distance in a direction perpendicular to the plane of the first surface; and a third surface created by the projection of the first surface by the distance in the direction perpendicular to the plane of the first surface, the surfaces being arranged such that the first surface abuts the second surface and the second surface abuts the third surface;
the continuous curve of the first and third surfaces being adapted to enable close packing of the elements.

11. The thermoelectric element of claim 10 wherein the element is a skutterudite compound comprising Sb and Co for n-type materials and Sb, Co, and Fe for p-type materials.

12. The skutterudite compound of claim 11 further comprising one or more of the elements of the group consisting of Na, K, Ca, Sr, Ba, La, Ce, Pr, Nd, Eu, Yb and Tl.

13. The thermoelectric element of claim 10 wherein the average grain size is less than 5 micrometers.

14. The thermoelectric element of claim 10 wherein the fracture stress is greater than 100 MPa.

15. A thermoelectric device comprising two substantially parallel electrically-insulating plates spaced apart from one another and at least one n-type, fine-grained polycrystalline net shape powder processed semiconductor thermoelectric element and at least one p-type, fine-grained polycrystalline net shape powder processed semiconductor thermoelectric element interposed between them;
the n-type and p-type elements having two vertically-aligned, generally identical, planar surfaces in mechanical contact with each of the plates and a third surface corresponding to the vertical projection of the plate-contacting surfaces over a distance equal to the plate separation; the form of the third surface adapted to enable the n-type and p-type elements to closely abut one another without contact; and
the plates further comprising electrically-conducting features to enable selective connection of the n-type and p-type elements and to enable connection to an electric circuit external to the device.

16. The thermoelectric device of claim 15 wherein the plate-contacting surfaces of the n-type and p-type elements are bounded by a smooth closed curve.

17. A method of making a thermoelectric device, the device comprising a plurality of legs of a same first shape of a first thermoelectric material, a plurality of legs of a same second shape of a second thermoelectric material, each leg having opposing ends with an electrode fixed to each end, the legs and electrodes being arranged in electrical circuit paths for the intended operation of the device; the method comprising:
preparing a powder of micron-size grains, uniformly of the composition of at least one of the first and second thermoelectric materials;
compacting and sintering measured quantities of the powder into consolidated bodies that are the net shape of the legs of at least one of thermoelectric materials; and, without alteration of the net shapes of the legs,
connecting the legs with their respective electrodes.
